(19) United States
(12) Patent Application Publication
(10) Pub. No.: US 2017/0213939 A1
(43) Pub. Date: Jul. 27, 2017

(54) SEMICONDUCTOR ELEMENT AND METHOD FOR MANUFACTURING SAME

(71) Applicant: NICHIA CORPORATION, Anan-shi (JP)

(72) Inventor: Shuji SHIOJI, Komatsushima-shi (JP)

(73) Assignee: NICHIA CORPORATION, Anan-shi (JP)

(21) Appl. No.: 15/414,021

(22) Filed: Jan. 24, 2017

(30) Foreign Application Priority Data
Jan. 25, 2016 (JP) 2016-011791

(51) Int. Cl. H01L 33/46; H01L 33/62

(52) U.S. Cl. CPC H01L 33/46; H01L 33/62; H01L 2933/0025; H01L 2933/0066

(57) ABSTRACT

A semiconductor element includes, in order from top to bottom, a semiconductor layer, a light-transmissive substrate, a dielectric multilayered film, and a reflective layer containing Ag as a major component and containing a metal oxide. A method for manufacturing the semiconductor element includes: forming a semiconductor layer on a first principal surface of a light-transmissive substrate, which has a second principal surface opposite to the first principal surface; forming a dielectric multilayered film on the second principal surface of the light-transmissive substrate; and forming a reflective layer containing Ag as a major component and containing a metal oxide on a side of the dielectric multilayered film opposite the light-transmissive substrate.

### CROSS-REFERENCE TO RELATED APPLICATION

This application claims priority to Japanese Patent Application No. 2016-011791, filed on Jan. 25, 2016, the entire disclosure of which is hereby incorporated by reference.

### BACKGROUND

1. Technical Field

The present disclosure relates to a semiconductor element and a method for manufacturing the semiconductor element.

2. Description of Related Art

There is known a semiconductor light emitting device having; a semiconductor light emitting element in which a semiconductor light emitting structure and electrodes are formed on a substrate; and a mounting board on which the semiconductor light emitting element is mounted through a eutectic solder. For such a semiconductor light emitting element, when for example the substrate side of the semiconductor light emitting element is fixed on the mounting board to have a greater output of light, there is known a structure such that a reflective layer is provided on a back surface of the substrate to increase reflectance of light toward the semiconductor light emitting structure, thus increasing the light extraction efficiency of the semiconductor light emitting element.

For example, Japanese Unexamined Patent Application Publication No. 2005-72148 discloses a nitride-based semiconductor element having: a crystal substrate; a reflective layer composed of metal material such as Ag and disposed below a back surface of the crystal substrate; an adhesion layer disposed between the crystal substrate and the reflective layer; and a protective layer disposed on a side of the reflective layer opposite the adhesion layer.

Japanese Unexamined Patent Application Publication No. 2007-243074 discloses a nitride-based light-emitting diode in which a semiconductor light emitting element is provided with a dielectric multilayered film for facilitating reflection of light.

### SUMMARY

A semiconductor element according to an embodiment of the present disclosure includes, in order from top to bottom: a semiconductor layer; a light-transmissive substrate; a dielectric multilayered film; and a reflective layer containing Ag as a major component and containing a metal oxide.

A method for manufacturing a semiconductor element according to an embodiment of the present disclosure includes the steps of forming a semiconductor layer on a first principal surface of a light-transmissive substrate, which has a second principal surface opposite to the first principal surface; forming a dielectric multilayered film on the second principal surface of the light-transmissive substrate; forming a reflective layer containing Ag as a major component and containing a metal oxide on a side of the dielectric multilayered film opposite the light-transmissive substrate.

The semiconductor element according to the embodiment of the present disclosure has high adhesion between the dielectric multilayered film and the reflective layer, and thus peeling-off is not likely to occur in the light reflective layer. The method for manufacturing a semiconductor element according to the embodiment of the present disclosure can manufacture a semiconductor element in which a reflective layer has high adhesion to a dielectric multilayered film and thus is not likely to peel off.

### BRIEF DESCRIPTION OF DRAWINGS

A more complete appreciation of the invention and many of the attendant advantages thereof will be readily obtained as the same becomes better understood by reference to the following detailed description when considered in connection with the accompanying drawings.

FIG. 1A is a schematic bottom view of a semiconductor light emitting element according to an embodiment of the present disclosure.

FIG. 1B is a schematic cross-sectional view of the semiconductor light emitting element according to the embodiment, taken along line IB-IB in FIG. 1A.

FIG. 2 is a schematic cross-sectional view showing an interface between a dielectric multilayered film and a reflective layer of the semiconductor light emitting element according to the embodiment and showing a state of a metal oxide in the reflective layer.

FIG. 3 is a flow chart illustrating a method for manufacturing the semiconductor light emitting element according to the embodiment.

FIG. 4A is a photograph of semiconductor light emitting elements, which have been cut into chips, of Working Example 1, taken from the side of a third metal layer of the semiconductor light emitting elements.

FIG. 4B is a photograph of semiconductor light emitting elements, which have been cut into chips, of Working Example 2, taken from the side of a third metal layer of the semiconductor light emitting elements.

FIG. 4C is a photograph of semiconductor light emitting elements, which have been cut into chips, of Working Example 3, taken from the side of a third metal layer of these semiconductor light emitting elements.

FIG. 4D is a photograph of semiconductor light emitting elements, which have been cut into chips, of Comparative Example 1, taken from the side of a third metal layer of the semiconductor light emitting elements.

FIG. 5 is a graph showing interface reflectances of reflective layers in Working Examples 1 to 3 and Comparative Example 1.

### DETAILED DESCRIPTION

An embodiment according to the present disclosure will be described below with reference to the accompanying drawings. It should be appreciated, however, that the embodiments described below are illustrations of a semiconductor element to give a concrete form to technical ideas of the present embodiments, and the present embodiments are not specifically limited to the description below. Unless otherwise specified, any dimensions, materials, shapes and relative arrangements of the parts described in the embodiments are given as an example and not as a limitation. Furthermore, the sizes, positional relations, and so forth of the members shown in the drawings may be exaggerated for the sake of clarity.

### Semiconductor Element

Description will be given of a semiconductor element according to the present embodiment. The semiconductor element according to the present embodiment is a semiconductor light emitting element.

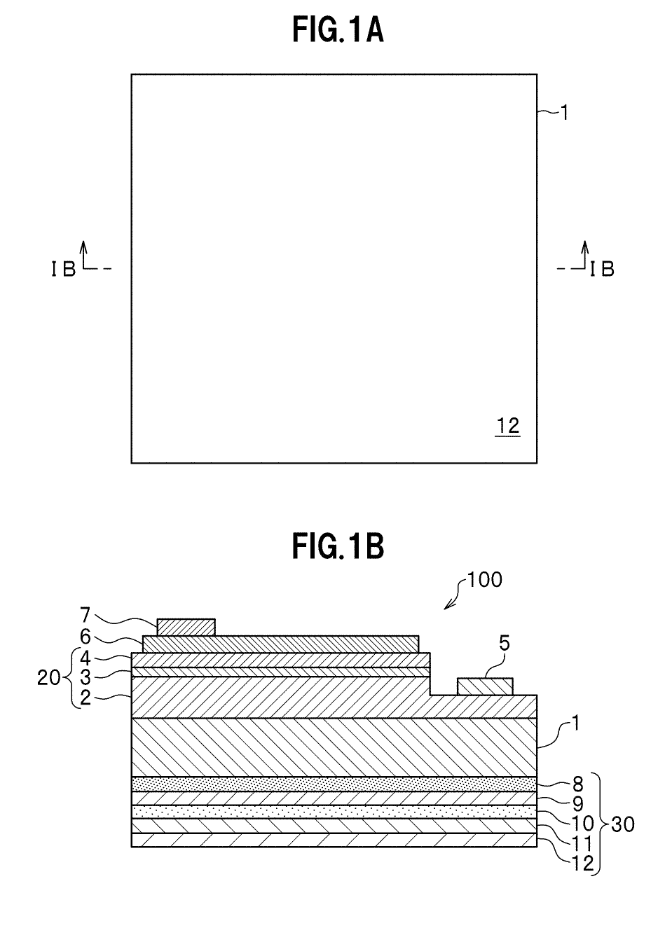

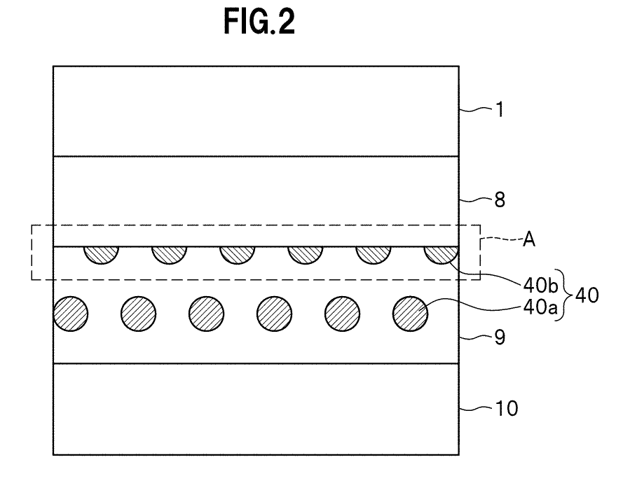

FIG. 1A is a schematic bottom view of a semiconductor light emitting element according to an embodiment of the present disclosure. FIG. 1B is a schematic cross-sectional view of the semiconductor light emitting element according to the embodiment, taken along line IB-IB in FIG. 1A. FIG. 2 is a schematic cross-sectional view showing an interface between a dielectric multilayered film and a reflective layer of the semiconductor light emitting element according to the embodiment and showing a state of a metal oxide in the reflective layer. Note that FIG. 2 schematically illustrates the state of the metal oxide in the reflective layer for the sake of clarity.

A semiconductor light emitting element 100 has: a light-transmissive substrate 1 having a first principal surface and a second principal surface opposite to the first principal surface; a semiconductor layer 20 disposed on the first principal surface of the light-transmissive substrate 1 and having, in order from the first principal surface, an n-type nitride semiconductor layer 2, a light emitting layer 3, and a p-type nitride semiconductor layer 4; and an n-side pad electrode 5, a p-side whole-surface electrode 6, and a p-side pad electrode 7. The semiconductor light emitting element 100 also has a layered film 30 disposed on the second principal surface of the light-transmissive substrate 1, in which layered film 30 a dielectric multilayered film 8, a reflective layer 9, a first metal layer 10, a second metal layer 11, and a third metal layer 12 are stacked in this order from the second principal surface. Note that a plurality of the semiconductor light emitting elements 100 are formed in a wafer, and each of the semiconductor light emitting elements 100 has regions having cut paths, along which the wafer is cut in a later-described wafer dividing step, to divide the wafer into individual chips.

### Light-Transmissive Substrate

The light-transmissive substrate 1 is not specifically limited. Examples of the light-transmissive substrate 1 on which a nitride semiconductor is grown include a sapphire (C-plane, A-plane, or R-plane) substrate, a spinel (MgAl₂O₄) substrate, an NGO (NdGaO₃) substrate, a LiAlO₂ substrate, and a GaN substrate. The light-transmissive substrate 1 is preferably an oxide substrate, and more preferably a wurtzite type crystal.

### Semiconductor Layers and Electrodes

The semiconductor layer 20 contains an n-type nitride semiconductor layer 2, a light emitting layer 3, and a p-type nitride semiconductor layer 4. Electrodes of the semiconductor light emitting element 100 include an n-side pad electrode 5, a p-side whole-surface electrode 6, and a p-side pad electrode 7.

The semiconductor light emitting element 100 according to the present embodiment has the n-type nitride semiconductor layer 2, the light emitting layer 3, the p-type nitride semiconductor layer 4, and the p-side whole-surface electrode 6, on the first principal surface of the light-transmissive substrate 1 in a stacked form. The semiconductor layer 20 has a region where the p-type nitride semiconductor layer 4, the light emitting layer 3, and a part of the n-type nitride semiconductor layer 2 are removed and the n-type nitride semiconductor layer 2 is partially exposed. The n-side pad electrode 5 of the semiconductor light emitting element 100 is disposed on that region where the n-type nitride semiconductor layer 2 is partially exposed. The p-side pad electrode 7 of the semiconductor light emitting element 100 is disposed on a region of the p-side whole-surface electrode 6.

Note that the upper side surface (first principal surface) and the underside surface (second principal surface) of the light-transmissive substrate 1 may have been processed to have unevenness to increase light extraction efficiency. A mask layer, a buffer layer, an intermediate layer or the like may be formed on the first principal surface of the light-transmissive substrate 1, beneath the semiconductor layer 20.

Preferably, In_{X}Al_{Y}Ga_{1-X-Y}N (0≦X, 0≦Y, X+Y<1) or the like is used as the material for the semiconductor layer 20. The p-side whole-surface electrode 6 is formed of an electrically-conductive oxide. Examples of the electrically-conductive oxide include an oxide including at least one selected from the group consisting of Zn, In, Sn, and Mg, such as ZnO, In₂O₃, SnO₂, and indium tin oxide (ITO). The material for the n-side pad electrode 5 and the p-side pad electrode 7 may be a single metal such as Ag, Al, Ni, Rh, Ti, Pt, Pd, Mo, Cr, W, Cu, or Au, or an alloy containing one of these metals as a major component. Alternatively, the n-side pad electrode 5 and the p-side pad electrode 7 may be composed of stacked layers of the above-described single metals or alloys each containing one of those metals as a major component.

### Dielectric Multilayered Film

The dielectric multilayered film 8 has a multi-layered structure in which two or more kinds of dielectric films having different refractive indices are alternately stacked. Specifically, the dielectric multilayered film 8 is a distributed Bragg reflector (DBR) film in which two or more kinds of films each having a different refractive index and a thickness of ¼n times a predetermined wavelength of light, where n denotes the refractive index, and is able to efficiently reflect light having the predetermined wavelength. Preferably, the material for the dielectric multilayered film 8 is an oxide of at least one element selected from Si, Ti, Zr, Nb, Ta, and Al. The dielectric multilayered film 8 preferably contains this oxide as a major component. More preferably, in the dielectric multilayered film 8, at least two or more kinds of dielectric films each containing an oxide of a respectively different one of those elements as their respective major components are repeatedly stacked.

The dielectric multilayered film 8 has a layered structure of oxides, an example of which is (Nb₂O_{5/}SiO₂)n, where n is a natural number. Moreover, the dielectric multilayered film 8 preferably has a layered structure in which two kinds of dielectric films having different refractive indices are stacked. Examples of materials for the two kinds of dielectric films having different refractive indices include SiO₂ for a dielectric film having a low refractive index, and Nb₂O₅, TiO₂, ZrO₂, and Ta₂O₅ each for a dielectric film having a high refractive index. The optical loss due to light absorption in the dielectric multilayered film 8 having such a structure is small as compared to that of a reflective film composed of a metal material.

Note that “the dielectric multilayered film 8 contains an oxide as a major component” means that the dielectric multilayered film 8 may be composed of the oxide only, or may be composed of the oxide and minute amounts of impurities or other minute amounts of elements. This also applies to similar descriptions below of elements contained in another layer.

### Reflective Layer

The reflective layer 9 is a silver alloy layer containing Ag as a major component and containing a metal oxide 40. The reflective layer 9 increases the reflectance of light reflected toward the semiconductor light emitting structure, and thus improves light extraction efficiency. As shown in FIGS. 1B and 2, the reflective layer 9 is provided beneath the entire region of a lower surface of the dielectric multilayered film 8. The metal oxide 40 is uniformly dispersed in the reflective layer 9. As shown in FIG. 2, since the reflective layer 9 contains the metal oxide 40, a pseudo transition layer, in which the metal oxide 40 and Ag in the reflective layer 9 coexist, is formed in the reflective layer 9 at an interface between the reflective layer 9 and the dielectric multilayered film 8. Such a pseudo transition layer increases the adhesion between the reflective layer 9 and the dielectric multilayered film 8 and thus increases reliability of the semiconductor light emitting element 100. Note that in FIG. 2, the reference sign A schematically indicates the pseudo transition layer.

Here, the coexistence of the metal oxide 40 and Ag at the interface between the reflective layer 9 and the dielectric multilayered film 8 means that a part of the metal oxide 40 exists in the interface and is, together with Ag, in contact with the dielectric multilayered film 8. The pseudo transition layer is not an actual layer and rather means a kind of layer produced by the presence of the metal oxide 40 and Ag at the interface.

The presence of the metal oxide 40 in the reflective layer 9 causes the reflective layer 9 to exhibit a pinning effect, which suppresses crystal grains of Ag, the major component of the reflective layer 9, from growing. This suppresses the growth of crystal grains due to the thermal history in the assembly process of the semiconductor device, so that the smoothness of the surface of the reflective layer 9 is kept and the occurring of voids in the reflective layer 9 is suppressed. This enables the reflective layer 9 to keep high reflectance and good heat dissipation properties.

Note that, in FIG. 2, reference sign 40a denotes the metal oxide 40 dispersed in the reflective layer 9 in granular form and reference sign 40b denotes the metal oxide 40 distributed at the interface between the reflective layer 9 and the dielectric multilayered film 8. Here, the metal oxide 40b does not constitute a layer by itself and a part of Ag is in contact with dielectric multilayered film 8. Here, the metal oxide 40b may be continuously distributed in a mesh form as long as the part of the Ag is in contact with the dielectric multilayered film 8. Note that, when the amount of the metal oxide 40 added to the reflective layer 9 is small, the amount of the metal oxide 40 distributed at the interface is small, and it is likely that the pseudo transition layer is formed such that the metal oxide 40b is distributed like islands at the interface. Here, the wording “distributed like islands” means that the metal oxide 40b is not continuously distributed but rather discretely distributed. Even in this case, however, it can be said that the metal oxide 40b and Ag coexist and thus constitute a pseudo transition layer.

Preferably, the metal oxide 40 in the reflective layer 9 is at least one substance selected from SiO₂, Al₂O₃, ZrO₂, TiO₂, ZnO, Ga₂O₃, Ta₂O₅, Nb₂O₅, In₂O₃, SnO₂, NiO, and HfO₂. More preferably, the metal oxide 40 in the reflective layer 9 is at least one substance selected from Ga₂O₃, Nb₂O₅, and HfO₂, in view of the adhesion between the reflective layer 9 and the dielectric multilayered film 8.

The content of the metal oxide 40 in the reflective layer 9 is only required to be greater than 0% by mass with respect to the total mass of the reflective layer 9. The metal oxide 40 having a content greater than 0% by mass increases the adhesion between the reflective layer 9 and the dielectric multilayered film 8. In view of the adhesion between the reflective layer 9 and the dielectric multilayered film 8, the content of the metal oxide 40 in the reflective layer 9 is preferably at least 0.01% by mass, and more preferably at least 0.02% by mass. In addition, in view of the reflectance (initial reflectance) of the reflective layer 9, the content of the metal oxide 40 in the reflective layer 9 is preferably at most 5% by mass, more preferably at most 4% by mass, and still more preferably at most 2.5% by mass.

Note that, the higher the transparency of the metal oxide 40 contained in the reflective layer 9, the higher the reflectance of the reflective layer 9. Thus, the higher the transparency of the metal oxide 40, the more the content of the metal oxide 40 in the reflective layer 9 may be.

The content of the metal oxide 40 in the reflective layer 9 can be determined by inductively coupled plasma atomic emission spectrometry (ICP-AES).

### First Metal Layer and Second Metal Layer

The first metal layer 10 and the second metal layer 11 are provided in this order on a surface of the reflective layer 9 opposite the dielectric multilayered film 8. The first metal layer 10 and the second metal layer 11 serve as a protective layer protecting the reflective layer 9. Preferably, the first metal layer 10 and the second metal layer 11 each contain an element selected from Ru, Rh, Pd, Os, Ir, Pt, Fe, Co, and Ni as a major component.

Using platinum group elements (Ru, Rh, Pd, Os, Ir, Pt), which are relatively stable, both chemically and thermally, as the metal material for the first metal layer 10 and the second metal layer 11 improves the effect of protecting the reflective layer 9 and thus preferably facilitates the functioning of the reflective layer 9. The same protection effect is expected by using iron group elements (Fe, Co, Ni), which are congeners of the platinum group elements, alternatively or in addition to platinum group elements.

Preferably, the first metal layer 10 and the second metal layer 11 contain respectively different elements of the above-described elements from each other as the respective major components. The first metal layer 10 and the second metal layer 11 each being composed of different metal materials from each other preferably enable the use of different properties of the different metal materials for the protection. That is, robust protection effect is easily obtained by the two-layer structure of layers containing different elements having different properties from each other.

### Third Metal Layer

The third metal layer 12 contains Au as a major component and is provided on a surface of the second metal layer 11 opposite the first metal layer 10.

When using an Au eutectic alloy die-bonding material to bond the semiconductor light emitting element 100 to a mounting board, provision of the third metal layer 12 improves the adhesion between the protective layer (first metal layer 10 and second metal layer 11) and the die-bonding material. In addition, the provision of the third metal layer 12 prevents components of the die-bonding material (e.g., Sn) from diffusing into the protective layer.

### Operation of Semiconductor Light Emitting Element

Description will be given of the operation of the semiconductor light emitting element 100 with reference to FIG. 1B.

In the semiconductor light emitting element 100, when electric current is provided through the n-side pad electrode 5 and p-side pad electrode 7 to the semiconductor layer 20, the light emitting layer 3 emits light. The light emitted from the light emitting layer 3 propagates in the semiconductor layer 20 and the light-transmissive substrate 1. The light has a part that travels upward in FIG. 1B and exits the semiconductor light emitting device 100 from the side of the semiconductor layer 20 (semiconductor light emitting structure). The light has a part that travels downward in FIG. 1B. This part is reflected upward by the dielectric multilayered film 8 and the reflective layer 9, and exits the semiconductor light emitting device 100 from the side of the semiconductor layer 20.

### Manufacturing Method of Semiconductor Light Emitting Element

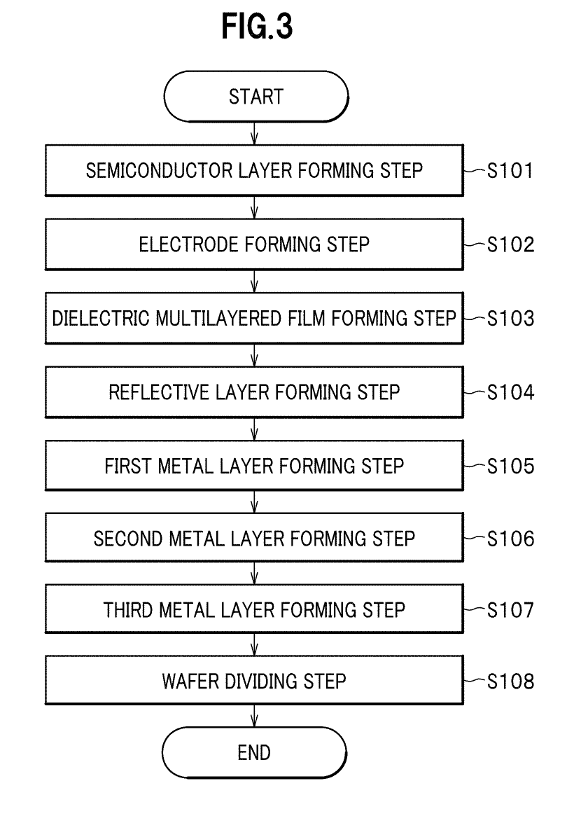

Next, description will be given of a manufacturing method for a semiconductor light emitting element according to the present embodiment. FIG. 3 is a flow chart illustrating a method for manufacturing the semiconductor light emitting element according to the embodiment.

The method for manufacturing the semiconductor light emitting element 100 according to the embodiment includes, as an example: a semiconductor layer forming step S101, an electrode forming step S102, a dielectric multilayered film forming step S103, a reflective layer forming step S104, a first metal layer forming step S105, a second metal layer forming step S106, a third metal layer forming step S107, and a wafer dividing step S108, which are carried out in this order. The materials, disposition and the like of the members are the same as those described above regarding the structure of the semiconductor light emitting device 100, and therefore the description thereof will be omitted as appropriate.

### Semiconductor Layer Forming Step, and Electrode Forming Step

In the semiconductor layer forming step S101, a semiconductor layer 20 is formed on a first principal surface of a light-transmissive substrate 1, which has a second principal surface opposite to the first principal surface. In the electrode forming step S102, a p-side whole-surface electrode 6, a p-side pad electrode 7, and an n-side pad electrode 5 are formed on the semiconductor layer 20. The semiconductor layer 20 and those electrodes are formed by a known manufacturing method, an example of which is described below.

The semiconductor layer 20 is formed by growing semiconductor layers of an n-type nitride semiconductor layer 2, a light emitting layer 3, and a p-type nitride semiconductor layer 4 in this order on the first principal surface of the light-transmissive substrate 1 by a metal organic vapor phase epitaxy (MOVPE) reaction apparatus. Next, a resist mask having a predetermined shape is formed on the p-type nitride semiconductor layer 4; then etching is carried out by a reactive ion etching (RIE) apparatus to etch the p-type nitride semiconductor layer 4, the light emitting layer 3, and the n-type nitride semiconductor layer 2, until an n-type contact layer of the n-type nitride semiconductor layer 2 is exposed; and then the resist is removed.

After that, an ITO film, for example, is formed on the entire surface of the wafer, i.e., the light-transmissive substrate 1 and the semiconductor layer 20 formed thereon, as a p-side whole-surface electrode 6 by a sputtering apparatus. Then a resist mask is formed such that the ITO film remains on almost entire surface of the p-type nitride semiconductor layer 4 after etching. After that, etching is carried out and then the resist is removed. Next, a mask is formed using a photoresist such that the mask has openings corresponding to predetermined regions in the area where the n-type nitride semiconductor layer 2 has been exposed and the area where the p-side whole-surface electrode 6 has been formed. Then, metal films for pad electrodes are successively formed on the wafer by a sputtering apparatus. Then, the photoresist is removed (lifted-off), to form an n-side pad electrode 5 and a p-side pad electrode 7. After that, the wafer is ground or polished on a side thereof opposite to the side of the wafer on which the n-side pad electrode 5 and the p-side pad electrode 7 have been formed, to reduce surface unevenness.

### Dielectric Multilayered Film Forming Step

In the dielectric multilayered film forming step S103, a dielectric multilayered film 8 is formed on the second principal surface of the light-transmissive substrate 1. The dielectric multilayered film 8 is formed by stacking a dielectric material on the second principal surface of the light-transmissive substrate 1 by for example a sputtering method or a vapor deposition method.

### Reflective Layer Forming Step

In the reflective layer forming step S104, a reflective layer 9 containing Ag as a major component and containing a metal oxide 40 is formed on a side of the dielectric multilayered film 8 opposite the light-transmissive substrate 1.

The reflective layer 9 may be formed by a simultaneous sputtering method using an Ag target (including pure silver target) and a metal oxide target, a sputtering method using an alloy target containing Ag and a metal oxide 40, or a vapor deposition method using an alloy deposition material containing Ag and a metal oxide 40. These sputtering methods and vapor deposition method are capable of forming a reflective layer 9 in which a metal oxide 40 is dispersed.

The alloy used in the alloy target or the alloy deposition material contains Ag as a major component and contains a metal oxide 40. Here, nanoscale particles of the metal oxide 40 are dispersed in the Ag alloy. An alternative to the vapor deposition method using an alloy deposition material to form the reflective layer 9 is to vapor-deposit a deposition material composed of Ag (including pure silver) and a deposition material composed of a metal oxide 40 at the same time.

Other conditions and procedures of the sputtering methods and vapor deposition method can follow known conditions and procedures.

### First Metal Layer Forming Step, Second Metal Layer Forming Step, and Third Metal Layer Forming Step

In the first metal layer forming step S105, a first metal layer 10 is formed on a side of the reflective layer 9 opposite the dielectric multilayered film 8. In the second metal layer forming step S106, a second metal layer 11 is formed on a side of the first metal layer 10 opposite the reflective layer 9. In the third metal layer forming step S107, a third metal layer 12 is formed on a side of the second metal layer 11 opposite the first metal layer.

The first metal layer 10, the second metal layer 11, and the third metal layer 12 are formed using known methods, examples of which include a vapor deposition method, a sputtering method, an ion beam-assisted deposition method, and a plating method.

### Wafer Dividing Step

In the wafer dividing step S108, the wafer in which the semiconductor layer 20, the electrodes, and the layered film 30 (the dielectric multilayered film 8, the reflective layer 9, the first metal layer 10, the second metal layer 11, and the third metal layer 12) have been formed is divided into chips.

Division of the wafer may be carried out by the following method, for example. In the wafer, cut regions each having a cut path, along which the wafer is cut later, are predetermined to define individual semiconductor light emitting elements. The wafer to be divided into chips is first irradiated by a laser beam from the side of the semiconductor layer 20 of the wafer along the cut paths. In this irradiation operation, the laser beam is emitted so as to be focused at an inner portion of the light-transmissive substrate 1. This produces altered portions in the light-transmissive substrate 1. The altered portions are band-like cutting grooves extending in a thickness direction of the light-transmissive substrate 1, i.e., in a perpendicular direction to the principal surfaces of the light-transmissive substrate 1. Examples of the source of the laser beam include a femtosecond laser. Next, the wafer is cut along the cut paths to be divided into chips of individual semiconductor light emitting elements. The wafer can be cut by scribing or dicing, for example.

Alternatively, the division of the wafer can be carried out by a combination of laser ablation and breaking. For example, the surface of the semiconductor layer 20 is irradiated by a strong laser beam along the cut paths to locally heat a surface layer of the semiconductor layer 20 along the cut paths to a high temperature to be evaporated. This produces grooves formed along the cut paths. Then, breaking is carried out along the grooves to divide the wafer into chips of individual semiconductor light emitting elements.

### Other Embodiments

The semiconductor light emitting element 100 of the above-described embodiment has a protective layer, which is constituted by the first metal layer 10 and the second metal layer 11, and the third metal layer 12. However, the semiconductor light emitting element 100 may be configured to not have either or both of the protective layer and the third metal layer 12. Moreover, the protective layer may be configured to have only either of the first metal layer 10 and the second metal layer 11.

In the method for manufacturing the semiconductor light emitting element 100, the dielectric multilayered film forming step S103, the reflective layer forming step S104, the first metal layer forming step S105, the second metal layer forming step S106, and the third metal layer forming step S107 may be carried out in this order and then the semiconductor layer forming step S101, the electrode forming step S102, and the wafer dividing step S108 may be carried out in this order.

### EXAMPLES

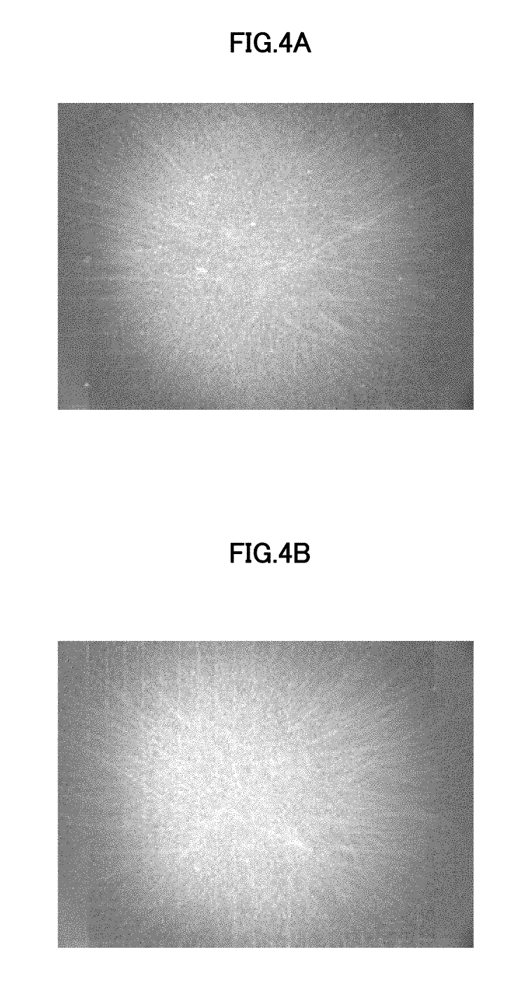

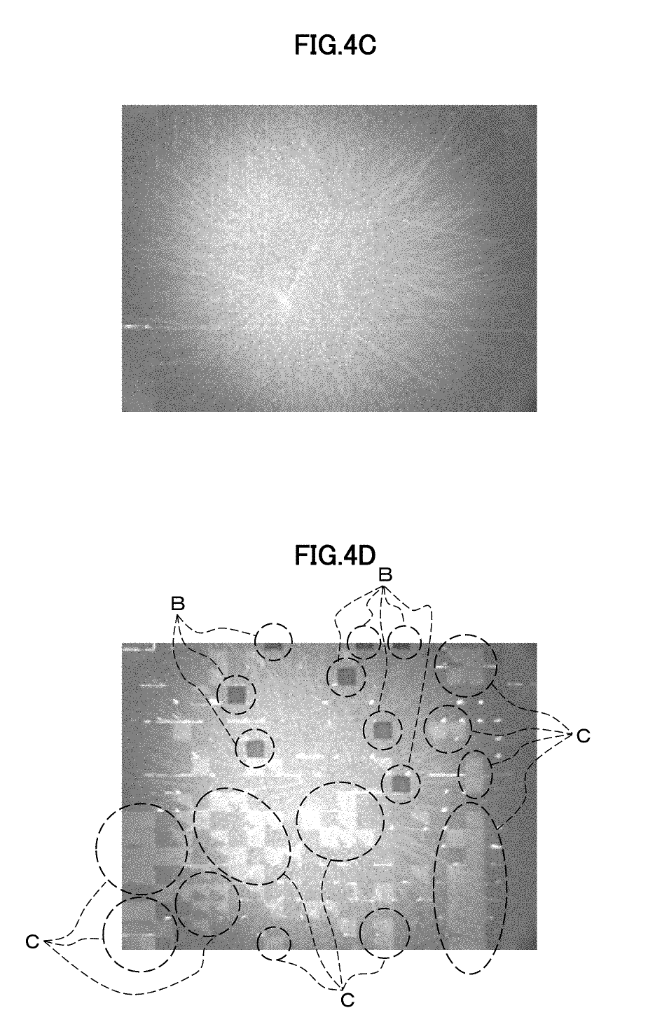

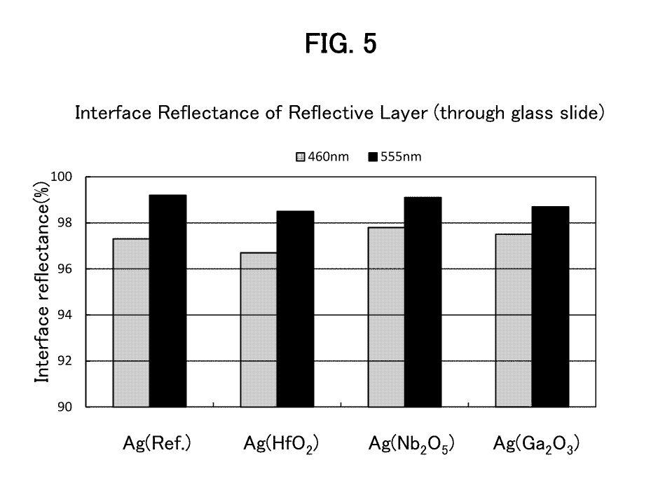

Hereinafter, description will be given of Working Examples according to the embodiments. FIGS. 4A to 4C are photographs of semiconductor light emitting elements, which have been cut into chips, of Working Examples 1 to 3, respectively taken from the side of their respective third metal layers. FIG. 4D is a photograph of a semiconductor light emitting elements, which have been cut into chips, of Comparative Example 1, taken from the side of its third metal layer. FIG. 5 is a graph showing the interface reflectances of the reflective layers in Working Examples 1 to 3 and Comparative Example 1. Note that, in FIGS. 4A to 4D, photographs are enlarged for ease of viewing.

### Working Example 1

Semiconductor light emitting elements according to the embodiment shown in FIGS. 1A and 1B were prepared in the following manner. First, on a first principal surface of a sapphire substrate, an n-type nitride semiconductor layer, a light emitting layer, a p-type nitride semiconductor layer were stacked in order from the n-type nitride semiconductor layer as semiconductor layers of the semiconductor light emitting elements. Next, for each of the semiconductor light emitting elements, an n-side pad electrode was formed on the n-type nitride semiconductor layer; a p-side whole-surface electrode was formed on the p-type nitride semiconductor layer; and a p-side pad electrode was formed on the p-side whole-surface electrode.

Next, a second principal surface of the sapphire substrate opposite to the first principal surface thereof was polished so that the sapphire substrate was thinned to a thickness of 200 μm. Then, a dielectric multilayered film (Nb₂O_{5/}SiO₂)n, where n is a natural number, was formed on the second principal surface of the sapphire substrate by a sputtering method so as to have a thickness of 2 μm. Further, a reflective layer containing HfO₂ and having a thickness of 120 nm was formed on the dielectric multilayered film by a simultaneous sputtering method using an Ag target and an HfO₂ target. Still further, by a sputtering method, an Ni film having a thickness of 100 nm was formed as a first metal layer on the reflective layer; an Rh film having a thickness of 200 nm was formed as a second metal layer on the first metal layer; and an Au film having a thickness of 500 nm was formed as a third metal layer on the second metal layer. A layered film was thus formed on the second principal surface of the sapphire substrate. Incidentally, the content of HfO₂ in the reflective layer was determined to be 0.24% by mass by ICP-AES analysis.

Next, the surface of the semiconductor layers were irradiated by a strong laser beam along cut paths defining individual semiconductor light emitting elements to evaporate the surface of the semiconductor layers along the cut paths, forming grooves along the cut paths. Then braking is carried out along thus formed grooves to divide the individual semiconductor light emitting elements into chips. Accordingly, the semiconductor light emitting elements of Working Example 1 were obtained.

### Working Example 2

Semiconductor light emitting elements of Working Example 2 were produced in the same manner as in Working Example 1, except that a reflective layer containing Nb₂O₅ was formed instead of the reflective layer containing HfO₂ of Working Example 1. The reflective layer containing Nb₂O₅ was formed by a simultaneous sputtering method using an Ag target and an Nb₂O₅ target. Incidentally, the content of Nb₂O₅ in the reflective layer was determined to be 0.07% by mass by ICP-AES analysis.

### Working Example 3

Semiconductor light emitting elements of Working Example 3 were produced in the same manner as in Working Example 1, except that a reflective layer containing Ga₂O₃ was formed instead of the reflective layer containing HfO₂ of Working Example 1. The reflective layer containing Ga₂O₃ was formed by a simultaneous sputtering method using an Ag target and a Ga₂O₃ target. Incidentally, the content of Ga₂O₃ in the reflective layer was determined to be 0.03% by mass by ICP-AES analysis.

### Comparative Example 1

Semiconductor light emitting elements of Comparative Example 1 were produced in the same manner as in Working Example 1, except that a pure silver layer was formed instead of the reflective layer containing HfO₂ of Working Example 1. The pure silver layer was formed by a sputtering method using an Ag target only.

An aggregate of the semiconductor light emitting elements of each of Working Example 1, Working Example 2, Working Example 3, and Comparative Example 1 was observed from the side of its third metal layer (side of the layered film) by a digital microscope “VHX-700F” manufactured by Keyence Corporation at a magnification of 25 times. As shown in FIGS. 4A to 4D, in Comparative Example 1, peeling-off occurred at many portions of the reflective layer, i.e., the pure silver layer, at the interface between the dielectric multilayered film and the reflective layer, whereas, in Working Examples 1, 2, and 3, no peeling-off occurred at the reflective layer containing HfO₂, the reflective layer containing Nb₂O₅, and the reflective layer containing Ga₂O₃, respectively, indicating improvement in the chip processability. Note that, in the photograph of Comparative Example ₁ shown in FIG. 4D, defects of chips are observed as black squares indicated by reference signs B. Note also that, in the photograph of Comparative Example 1 shown in FIG. 4D, peeling-off is observed as a group of square portions indicated by reference signs C and having a different brightness compared to the same corresponding portions in the photographs of Working Examples 1 to 3 shown in FIGS. 4A to 4C.

The reflective layer containing HfO₂ produced in Working Example 1, the reflective layer containing Nb₂O₅ produced in Working Example 2, the reflective layer containing Ga₂O₃ produced in Working Example 3, and the reflective layer containing pure silver produced in Comparative Example 1 were examined with respect to the reflectances of their interfaces to their dielectric multilayered films. Specifically, each of the reflective layers were formed on a glass slide, and the interface reflectance of the reflective layer through the glass slide was determined using a “U-3010” spectrophotometer (ROM Ver. 2520 10) manufactured by Hitachi High-Technologies Corporation (C). As shown in FIG. 5, the reflective layers containing the metal oxides of Working Examples 1 to 3 had the same level of reflectance of the reflective layer of Comparative Example 1, which contained no metal oxide. From this result, it is understood that a reflective layer to which a metal oxide is added at the above-described content is able to maintain the same level of reflectance as a pure silver layer.

Moreover, as described, in Comparative Example 1, peeling-off occurred at many portions of the reflective layer containing no metal oxide in the interface to the dielectric multilayered film, whereas, in Working Examples 1 to 3, no peeling-off occurred in the reflective layers each containing a metal oxide. This indicates the high adhesion of the reflective layers of Working Examples 1 to 3 to their respective dielectric multilayered films.

The semiconductor element and the method of manufacturing the same according to the present invention have been specifically described in the embodiments of the present invention, but the scope of the present invention is not limited to the above description and should be construed broadly based on the scope of claims. In addition, various modifications and variations made based on the above description are also included in the scope of the present invention, as a matter of course.

The semiconductor elements according to the embodiments of the present disclosure are applicable to all the semiconductor light emitting device using light emitting elements, such as various lighting equipment, illumination devices for vehicle, displays, and indicators. In addition, the semiconductor elements according to the embodiments of the present disclosure are also applicable to devices using optical elements such as light receiving devices, semiconductor devices such as power transistors, and semiconductor electronic devices.

What is claimed is:

1. A semiconductor element comprising, in order from top to bottom:
a semiconductor layer;
a light-transmissive substrate;
a dielectric multilayered film; and
a reflective layer containing Ag as a major component and containing a metal oxide.

2. The semiconductor element according to claim 1, wherein the metal oxide is at least one selected from Ga₂O₃, Nb₂O₅, and HfO₂.

3. The semiconductor element according to claim 1, wherein a content of the metal oxide is at least 0.01% by mass and at most 5% by mass with respect to the total mass of the reflective layer.

4. The semiconductor element according to claim 1, wherein the metal oxide is dispersed in the reflective layer.

5. The semiconductor element according to claim 1, further comprising a first metal layer beneath the reflective layer and a second metal layer beneath the first metal layer.

6. The semiconductor element according to claim 5, wherein each of the first metal layer and the second metal layer contains an element selected from Ru, Rh, Pd, Os, Ir, Pt, Fe, Co, and Ni, as a major component.

7. The semiconductor element according to claim 6, wherein the first metal layer and the second metal layer contain different elements from each other as the respective major component.

8. The semiconductor element according to claim 5, further comprising a third metal layer containing Au as a major component beneath the second metal layer.

9. The semiconductor element according to claim 1, wherein the dielectric multilayered film contains an oxide of at least one element selected from Si, Ti, Zr, Nb, Ta, and Al as a major component.

10. The semiconductor element according to claim 1, wherein the dielectric multilayered film is a distributed Bragg reflector film.

11. The semiconductor element according to claim 1, wherein the semiconductor element is a semiconductor light emitting element.

12. A method for manufacturing a semiconductor element, comprising the steps of:
forming a semiconductor layer on a first principal surface of a light-transmissive substrate, the light-transmissive substrate having a second principal surface opposite to the first principal surface;
forming a dielectric multilayered film on the second principal surface of the light-transmissive substrate; and
forming a reflective layer containing Ag as a major component and containing a metal oxide on a side of the dielectric multilayered film opposite the light-transmissive substrate.

13. The method for manufacturing a semiconductor element according to claim 12, wherein the reflective layer is formed by a simultaneous sputtering method using an Ag target and a target of the metal oxide, a sputtering method using an alloy target including Ag and the metal oxide, or a vapor deposition method using an alloy deposition material including Ag and the metal oxide.

14. The method for manufacturing a semiconductor element according to claim 12, wherein the metal oxide is at least one selected from Ga₂O₃, Nb₂O₅, and HfO₂.

15. The method for manufacturing a semiconductor element according to claim 12, wherein a content of the metal oxide is at least 0.01% by mass and at most 5% by mass with respect to the total mass of the reflective layer.

16. The method for manufacturing a semiconductor element according to claim 12, wherein the metal oxide is dispersed in the reflective layer.

17. The method for manufacturing a semiconductor element according to claim 12, further comprising the steps of:
after forming the reflective layer, forming a first metal layer on a side of the reflective layer opposite the dielectric multilayered film; and
forming a second metal layer on a side of the first metal layer opposite the reflective layer.

18. The method for manufacturing a semiconductor element according to claim 17, wherein each of the first metal layer and the second metal layer is formed using a material containing an element selected from Ru, Rh, Pd, Os, Ir, Pt, Fe, Co, and Ni, as a major component.

19. The method for manufacturing a semiconductor element according to claim 18, wherein the first metal layer and the second metal layer are respectively formed using different materials containing different elements from each other as the respective major component.

20. The method for manufacturing a semiconductor element according to claim 17, further comprising:
after forming the second metal layer, forming a third metal layer using a material containing Au as a major component on a side of the second metal layer opposite the first metal layer.

21. The method for manufacturing a semiconductor element according to claim 12, wherein the dielectric multilayered film is formed using a material containing an oxide of at least one element selected from Si, Ti, Zr, Nb, Ta, and Al.

22. The method for manufacturing a semiconductor element according to claim 12, wherein the dielectric multilayered film is a distributed Bragg reflector film.

23. The method for manufacturing a semiconductor element according to claim 12, wherein the semiconductor element is a semiconductor light emitting element.
